(19) United States
(12) Patent Application Publication
(10) Pub. No.: US 2002/0197145 A1
(43) Pub. Date: Dec. 26, 2002

(54) Substrate processing apparatus and a method for fabricating a semiconductor device by using same

(75) Inventors: Tetsuo Yamamoto, Tokyo (JP); Makoto Ozawa, Tokyo (JP); Shuji Yonemitsu, Tokyo (JP); Toshimitsu Miyata, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/106,246

(22) Filed: Mar. 27, 2002

(30) Foreign Application Priority Data
Jun. 21, 2001 (JP) 2001-188775

(51) Int. Cl. B65G 49/07; C23C 16/00

(52) U.S. Cl. 414/806; 118/719; 118/724; 414/222.07; 414/935; 414/937

(57) ABSTRACT

A substrate processing apparatus includes a substrate holder for holding a plurality of wafers and being loaded therewith into a process tube through an opening in the process tube, in which a plurality of the wafers are processed, a wafer transfer system for charging a plurality of the wafers to the substrate holder, a boat waiting chamber installed on a line passing through the opening in the process tube and substantially hermetically accommodating the substrate holder before and after the substrate holder is loaded into and unloaded from the process tube and a wafer transfer chamber for substantially hermetically accommodating the wafer transfer system. An oxygen concentration of the boat waiting chamber is different from that of the wafer transfer chamber.

### FIELD OF THE INVENTION

The present invention relates to a substrate processing method and apparatus to be used in fabricating a semiconductor device; and more particularly, to a method and an apparatus capable of preventing a natural oxide film and/or contamination from being formed on a to-be-processed substrate and applicable to, e.g., a batch-type vertical apparatus which performs a diffusion or a CVD (chemical vapor deposition) process to form CVD layers such as an insulating or a metal layer.

### BACKGROUND OF THE INVENTION

In a substrate processing apparatus such as a batch-type vertical apparatus for performing a diffusion or a CVD process (referred to as a substrate processing apparatus hereinafter), to-be-processed wafers are loaded thereinto while being kept in a carrier. Two kinds of carriers have been conventionally used. One is a box-shaped cassette having a pair of openings on two opposite sides and the other is a box-shaped FOUP (front opening unified pod; hereinafter, pod) having an opening on one side thereof with a pod cap removably mounted thereon.

In case where the pod is used as a wafer carrier, since the wafers can be kept protected from particulates in the ambient atmosphere while being transferred, a degree of cleanliness of the wafers could be maintained. As a result, a level of cleanliness required for a clean room of the substrate processing apparatus may be lowered, which in turn reduces cost for the maintenance of the clean room. For such reasons, the pod is gaining popularity as the carrier in the substrate processing apparatus recently.

Such conventional substrate processing apparatuses that use the pod as a wafer carrier are described in Japanese Patent Application Laid-open Nos. 6-077152 and 7297257. In the former application, there is disclosed a batch-type CVD apparatus including a housing, wherein the housing accommodates a process tube, a boat elevator, a wafer transfer device, a cassette accommodating chamber, a buffer cassette accommodating chamber and the like. The housing, the buffer cassette accommodating chamber and a boat waiting room are made in a normal pressure air-tight structure and inner gases therein are replaced by a nitrogen gas in order that the batch-type vertical apparatus is capable of preventing natural oxidization from being formed on wafers being transferred and waiting for a subsequent process in the housing.

In the latter application, there is disclosed another batch-type CVD apparatus using an SMIF (standard mechanical interface) pod, wherein each SMIF pod contains a cassette holding a plurality of wafers. For this batch-type CVD apparatus, a boat loading chamber in which a boat waits for being loaded into a process chamber, and a wafer transfer chamber in which a wafer transfer device for transferring wafers between the boat and a cassette extracted from the SMIF pod are respectively configured to have a nitrogen gas ambience therein. Accordingly, the level of the cleanliness of the clean room can be lowered even though the cassette is used.

However, both the conventional substrate processing apparatuses described above have a critical deficiency that an abundant nitrogen gas is required.

### SUMMARY OF THE INVENTION

It is, therefore, an object of the present invention to provide a substrate processing apparatus and a method for fabricating a semiconductor device, which are capable of preventing a formation of a natural oxide film and a contamination on a to-be-processed substrate.

In accordance with one aspect of the invention, there is provided a substrate processing apparatus, which includes: a substrate holder for holding a plurality of wafers and being loaded therewith into a process tube through an opening in the process tube, in which a plurality of the wafers are processed; a wafer transfer system for charging a plurality of the wafers to the wafer holder; a boat waiting chamber installed on a line passing through the opening in the process tube and substantially hermetically accommodating the substrate holder before and after the substrate holder is loaded into and unloaded from the process tube; and a wafer transfer chamber for substantially hermetically accommodating the wafer transfer system, wherein an oxygen concentration in the boat waiting chamber is different from that in the wafer transfer chamber.

In accordance with another aspect of the invention, there is provided a method for fabricating a semiconductor device by using a substrate processing apparatus having: a substrate holder for holding a plurality of wafers and being loaded therewith into a process tube through an opening in the process tube, in which a plurality of the wafers are processed; a wafer transfer system for charging a plurality of the wafers to the wafer holder; a boat waiting chamber installed on a line passing through the opening in the process tube and substantially hermetically accommodating the substrate holder before and after the substrate holder is loaded into and unloaded from the process tube; and a wafer transfer chamber for substantially hermetically accommodating the wafer transfer system, wherein an oxygen concentration in the boat waiting chamber is different from that in the wafer transfer chamber.

In the substrate processing apparatus for performing a heat treatment on a substrate, the formation of the natural oxide film depends on a correlation between temperature and oxygen. The inventors of the present invention find that the formation of the natural oxide film is increased while substrates are waiting to be loaded into a process tube. Accordingly, in order to prevent such formation of the natural oxide film as described above, an oxygen concentration in a boat waiting chamber in which the wafers wait to be loaded into the process tube has to be reduced. However, a great amount of a nitrogen gas will be required if the nitrogen gas is supplied to the waiting room in order to decrease the oxygen concentration in the boat waiting chamber after the waiting room is opened to the atmosphere to transfer the substrate into thereinto. Further, in such case, moisture in the atmosphere is condensed and attached on an inner surface of the waiting room and the attached moisture is difficult to remove from the waiting room. In addition, it is quite possible that the atmosphere introduced into the boat waiting chamber will be introduced into the process tube. Therefore, by setting the oxygen concentration in the waiting room less than that in a room for transferring the substrates, the formation of the natural oxide film and a contamination can be prevented with a reduced amount of the nitrogen gas.

### BRIEF DESCRIPTION OF THE DRAWINGS

The above and other objects and features of the present invention will become apparent from the following description of preferred embodiments given in conjunction with the accompanying drawings, in which:

FIG. 1 schematically shows a perspective view of a batch-type CVD apparatus in accordance with a first preferred embodiment;

FIG. 2 describes a horizontal cross-sectional view of the batch-type CVD apparatus of FIG. 1;

FIG. 3 illustrates a vertical cross-sectional view of the batch-type CVD apparatus of FIG. 1;

FIG. 4 offers a vertical cross-sectional view of the batch-type CVD apparatus of FIG. 1 with a boat loaded into a process tube;

FIG. 5 provides a side view of a batch-type CVD apparatus with a partial portion cross-sectioned in accordance with a second preferred embodiment;

FIG. 6 depicts a partial horizontal cross-sectional view of a batch-type CVD apparatus in accordance with a third preferred embodiment of the present invention; and

FIG. 7 represents a partial horizontal cross-sectional view of a batch-type CVD apparatus in accordance with a fourth preferred embodiment of the present invention.

### DETAILED DESCRIPTION OF THE PREFERRED EMBODIMENTS

Preferred embodiments of the present invention will now be described with reference to the accompanying drawings.

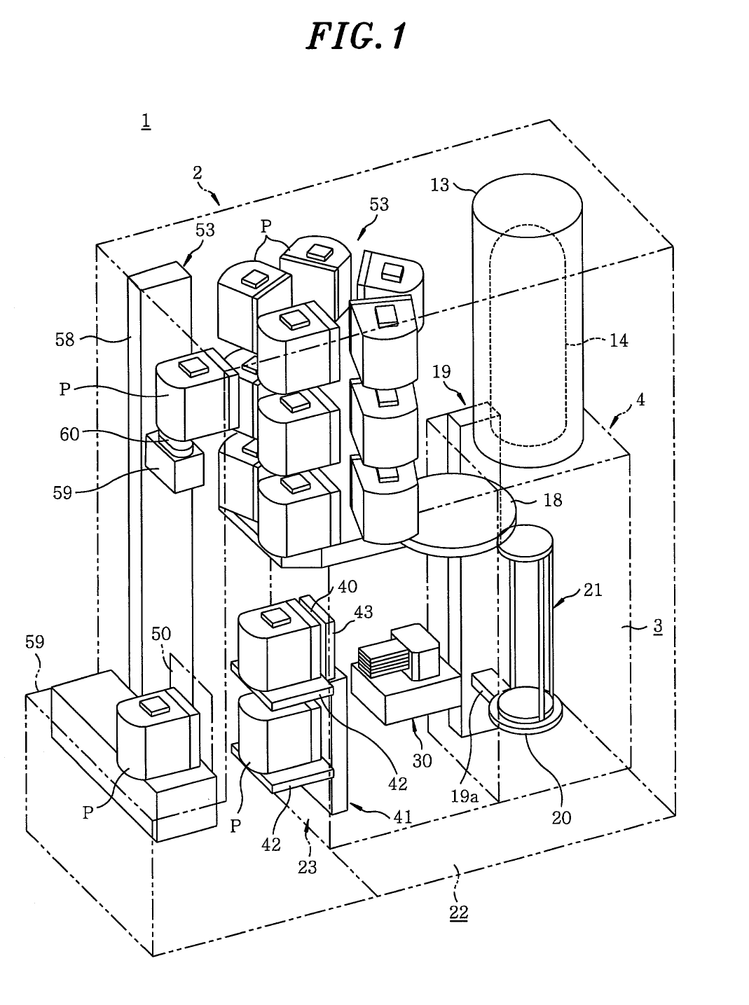

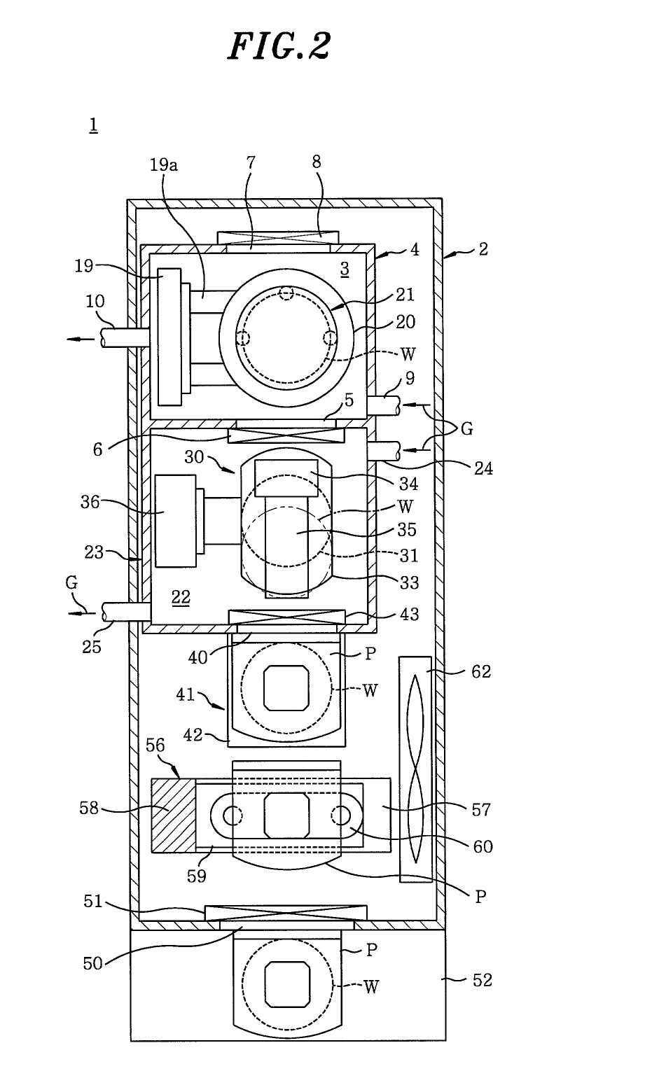

In the preferred embodiments of the present invention, a substrate processing apparatus is a batch-type vertical apparatus for performing a diffusion and a CVD process (referred to as batch-type CVD apparatus hereinafter), which is used to diffuse impurities or form a CVD layer, e.g., an insulating or a metal layer, on a wafer during a fabrication process of a semiconductor device. The batch-type CVD apparatus uses a pod P as a wafer carrier. Further, in the following description, a front, a rear, a left and a right side are defined with reference to FIG. 2, wherein the front side refers to where a pod stage 52 is located; the rear side refers to a side opposite to the front side, i.e., where a heater unit 13 (shown in FIG. 1) is located; the right side refers to where a clean air unit 62 is located; the left side refers to where an elevator 36 of a wafer transfer system 30 is located.

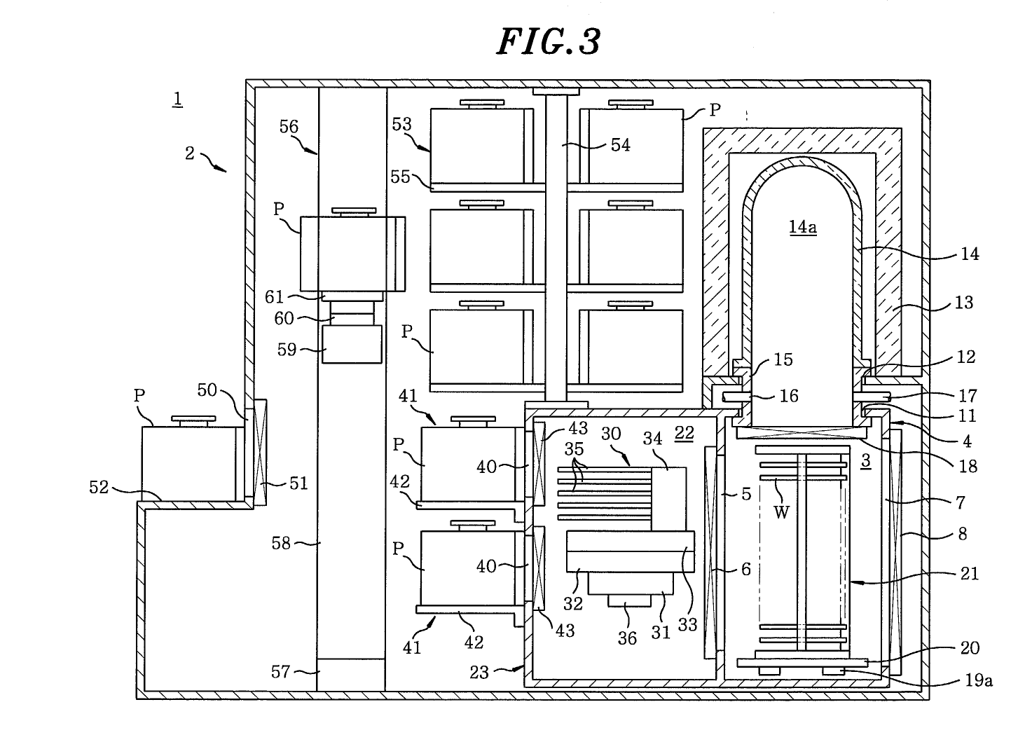

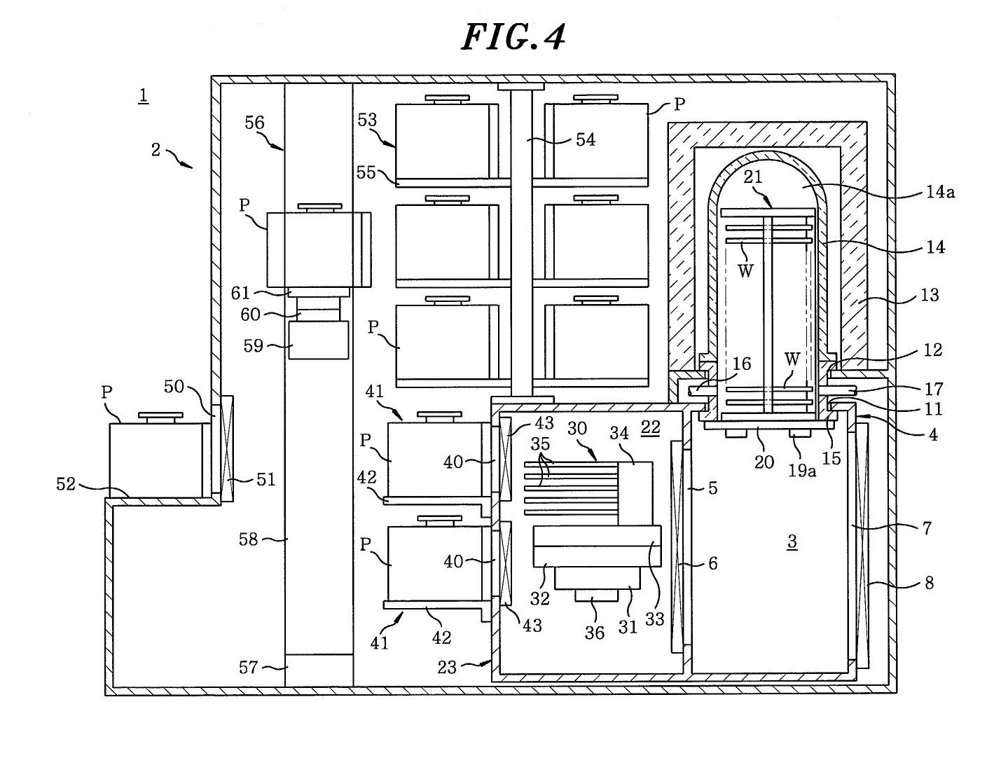

As shown in FIGS. 1 to 4, the batch-type CVD apparatus 1 includes a box-shaped housing 2 made of an angle steel or a steel plate. Installed in a rear portion of the housing 2 is a boat waiting chamber 4, which forms an antechamber 3 therein, i.e., a space accommodating a boat 21 as will be described later. The boat waiting chamber 4 is an airtight chamber capable of withstanding against the atmospheric pressure. Formed in a front wall of the boat waiting chamber 4 is a first wafer loading/unloading opening 5, which is closed or opened by a gate 6. There is a maintenance opening 7 formed in a rear wall of the boat waiting chamber 4 and closed by a gate 8 normally, through which the boat 21 is loaded into or unloaded from the antechamber 3. In addition, as shown in FIG. 2, a supply line 9 for supplying a nitrogen gas G to the antechamber 3 and an exhaust line 10 for evacuating the antechamber 3 are connected to the boat waiting chamber 4 so that they can communicate with the antechamber 3 and make the nitrogen gas G flow through the antechamber 3.

Shown in FIGS. 1, 3 and 4, in an upper rear portion of the housing 2, a heater unit 13 is vertically installed and a cylinder-shaped process tube 14 having a closed upper end and an open lower end is concentrically disposed therein. The process tube 14 is supported by the housing 2 through a manifold 15, which is concentrically inserted in manifold openings 11, 12 respectfully formed in a top wall of the boat waiting chamber 4 and a horizontal partition portion of the housing 2 to be supported by the housing 2. A supply line 16 for introducing a source gas or a purge gas into a process room 14a confined by the process tube 14 and an exhaust line 17 for evacuating the process room 14a are connected to the manifold 15. A lower opening of the manifold 15 serving as a furnace mouth of the process tube 14 is configured to be closed or opened by a shutter 18.

As shown in FIGS. 1 and 2, installed in the antechamber 3 is a boat elevator 19 for raising or lowering the boat 21. The boat elevator 19 includes a feed screw vertically and rotatably disposed in the antechamber 3, a motor for rotating the feed screw clockwise or counterclockwise and a lift arm 19a screw connected to the feed screw in such a manner that it is raised and lowered by the rotation of the feed screw 19. Further, it is preferably to use a ball screw mechanism for the connection between the feed screw and the lift arm 19a in order to confer smooth operation to the boat elevator 19 without increasing backlash.

At free ends of the lift arm 19a, a sealing cap 20 is horizontally attached. The sealing cap 20 is configured to airtightly close the lower opening of the manifold 15 serving as the furnace mouth and support the boat 21 uprightly. The boat 21 has a plurality of support rods (three support rods in the preferred embodiments), which are configured to hold a plural number, e.g., from 50 to 150, of the wafers W horizontally with their centers vertically aligned. The boat 21 is loaded into and unloaded from the process room 14a of the process tube 14 in accordance with the ascent and descent motion of the sealing cap 20 by the boat elevator 19.

As shown in FIGS. 1 to 4, installed in front of the boat waiting chamber 4 in the housing 2 is a wafer transfer chamber 23 confining a wafer transfer room 22 therein for accommodating the wafer transfer system 30. The wafer transfer chamber 23 is an airtight chamber capable of withstanding against the atmospheric pressure. As shown in FIG. 2, a supply line 24 for supplying the nitrogen gas G to the wafer transfer room 22 and an exhaust line 25 for evacuating the wafer transfer room 22 are connected to the wafer transfer chamber 23 so that they can communicate with the wafer transfer room 22 and make the nitrogen gas G flow through the wafer transfer room 22.

Installed in the wafer transfer room 22 is the wafer transfer system 30 for loading and unloading the wafers W into and from the boat 21. The wafer transfer system 30 has a rotary actuator 31 for rotating a first linear actuator 32 disposed thereon in a horizontal plane. The first linear actuator 32 is configured to move a second linear actuator 33 disposed thereon in a plane. The second linear actuator 33 is configured to move a movable block 34 in a horizontal plane, which is installed on an upper surface of the second linear actuator 33. The movable block 34 has plural pairs of tweezers 35 (in this example, five pairs of tweezers) horizontally disposed with a same vertical distance therebetween. The whole wafer transfer system 30 is raised or lowered by the elevator 36 having, e.g., a feed screw mechanism.

As shown in FIGS. 1 to 4, vertically formed in a front wall of the wafer transfer chamber 23 are two wafer loading/unloading openings 40 through which the wafers W are transferred to or from the wafer transfer room 22. There is a pod opener 41 at each wafer loading/unloading openings 40. The pod opener 41 has a loading port 42 for providing a place where the pod P is disposed and a pod cap removing/restoring device 43 for removing or restoring a cap of the pod P disposed on the loading port 42. The pod P is transferred to and from the pod loading port 42 by a pod transfer system 56, as will be described later.

Formed in a front wall of the housing 2 is a pod loading/unloading opening 50 through which an outer space of the housing 2 communicates with an inner space thereof. The pod loading/unloading opening 50 is closed or opened by a front shutter 51. Installed in front of the pod loading/unloading opening 50 is a pod stage 52 on which the pod P is disposed and arranged. The pod P is transferred to or from the pod stage 52 by a pod transfer assembly (not shown).

As shown in FIGS. 1, 3 and 4, installed in the upper central portion of the housing 2 is a rotatable pod shelf 53 configured to store a plurality of the pods P therein. The rotatable pod shelf 53 has a supporting rod 54 vertically disposed on an upper wall of the wafer transfer chamber 23, which intermittently rotates, and a plurality of shelf plates 55 disposed radially at a top, a middle and a bottom portion of the supporting rod 54, each shelf plate 55 being configured to have one pod P thereon.

As shown in FIGS. 1 to 4, installed between the pod stage 52, the pod shelf 53 and the loading port 42 of the pod opener 41 in the housing 2 is the pod transfer system 56 configured to transfer the pod P between the pod stage 52 and the pod shelf 53 and between the pod shelf 53 and the pod loading port 42 of the pod opener 41. The pod transfer system 56 has a linear actuator 57 disposed on a bottom wall of the housing 2 along a front width, a pod elevator 58 moved by the linear actuator 57 along a left-right direction, a robot arm 60 supported by a lift platform 59 of the pod elevator 58 and a pod holding port 61 attached to the robot arm 60. The pod P is transferred in accordance with a three-dimensional movement of the pod holding port 61 made by the robot arm 60 while being supported from a bottom by the pod holding port 61.

Further, as shown in FIG. 2, installed at an opposite portion to the pod elevator 58 of the pod transfer system 56 in the housing 2 is the clean air unit 62 configured to supply clean air to an inner space of the housing 2.

A film forming process included in a method for fabricating a semiconductor device, the method being one aspect of the present invention, will now be described with reference to the batch-type CVD apparatus 1 described above.

As shown in FIGS. 1 to 4, after the pod P is disposed on the pod stage 52, the pod loading/unloading opening 50 is opened by opening the front shutter 51. Then, the pod P on the pod stage 52 is lifted and transferred into the housing 2 through the pod loading/unloading opening 50 by the pod holding port 61 of the pod transfer system 56. The pod P brought into the housing 2 is transferred to the predetermined shelf plate 55, substitutes other pod P disposed previously thereon and stored temporarily thereon.

The pod P disposed on the shelf plate 55 is picked up and transferred to the pod opener 41 to be loaded on the pod loading port 42 by the pod transfer system 56. At this time, the second wafer loading/unloading opening 40 of the pod opener 41 is closed by the pod cap removing/restoring device 43 and the wafer transfer room 22 is filled with the nitrogen gas G that is supplied thereto through the supply line 24 and is exhausted therefrom through the exhaust line 25. A concentration of oxygen in the wafer transfer room 22 is set to be equal to or less than 20 ppm, which is far less than that in the housing 2.

The pod P loaded on the loading port 42 is pushed to the front wall of the wafer transfer chamber 23 in such a manner that a pressurized close contact between a periphery of an opening formed in a front wall of the pod P facing the wafer transfer chamber 23 and a periphery of the second wafer loading/unloading opening 40 can be made. Then, the pod cap removing/restoring device 43 opens the opening of the pod P by removing a cap of the pod P. At this moment, the first wafer loading/unloading opening 5 formed in the front wall of the boat waiting chamber 4 separating the wafer transfer room 22 from the antechamber 3 is closed by the gate 6 and the wafer transfer room 22 and the antechamber 3 are filled with the nitrogen gas G respectively flowing from the supply lines 9, 24 to the exhaust lines 10, 25. Further, the oxygen concentration in the antechamber 3 (equal to or less than 1 ppm) is less than that in the wafer transfer chamber 23 (equal to or less than 20 ppm). It should be noted that the amount of flow of the nitrogen gas G in the antechamber 3 is set to be larger than that in the wafer transfer room 22 and that the inner pressure in the antechamber 3 is set to be greater than that in the wafer transfer room 22. Therefore, an ambience in the wafer transfer room 22 is not introduced into the antechamber 3 and the oxygen concentration in the antechamber 3 is rarely affected by the ambience of the wafer transfer room 22.

Next, a plurality of the wafers W contained in the pod P is picked and transferred to the wafer transfer room 22 through the first second wafer loading/unloading opening 5 by plural pairs of tweezers 35. Then, the first wafer loading/unloading opening 5 formed in the front wall of the boat waiting chamber 4 is opened by removing the closure member 6 and the wafers W supported by the tweezers 35 are transferred to the antechamber 3 through the first wafer loading/unloading opening 5 to be loaded into the boat 21.

Since the inner pressure of the antechamber 3 is set to be greater than that in the wafer transfer chamber 23, the ambience of the wafer transfer room 22, i.e., the nitrogen gas G containing atmosphere as an impurity is prevented from flowing into the antechamber 3. That is, the oxygen concentration in the antechamber 3 can be kept less than that in the wafer transfer room 22. In addition, since the furnace mouth of the process tube 14 is tightly closed by the shutter 18, the heat radiated from the inside of the process tube 14 does little harm to the wafers W. Therefore, there is little possibility that a natural oxide film is formed on the wafers W.

The tweezers 35 are moved back to the wafer transfer room 22 from the antechamber 3 after charging the wafers W into the boat 21. Then, the operation of the wafer transfer system 30 described above is repeated, so that all wafers W contained in the pod P on the pod loading port 42 are charged into the boat 21.

Further, while the wafer transferring process for the pod P on the upper or lower pod opener 41 is being performed, another pod P stored in the rotatable pod shelf 53 is transferred to the lower or upper pod opener 41 by the pod transfer system 56 and then the pod opener 41 starts to perform its pod cap opening process, i.e., removing the cap of the pod P. Since the pod transferring and the pod cap opening process for one loading port 42 are performed during the wafer transferring process for the other loading port 42 as described above, subsequent wafer transferring process can be performed right after the previous wafer transferring process ends. That is, since the wafer transfer system 30 can transfer the wafers W to the boat 21 continuously without spending time on waiting for the pod transferring process and the pod cap opening process, the throughput of the batch-type CVD apparatus 1 can be increased.

After a predetermined number of the wafers W are charged into the boat 21, the boat 21 is raised by the boat elevator 19 to be loaded into the process room 14a of the process tube 14. At this moment, the first wafer loading/unloading opening 5 formed in the front wall of the boat waiting chamber 4 separating the wafer transfer room 22 from the antechamber 3 is closed by the gate 6, and the antechamber 3 is filled with the nitrogen gas G that is supplied thereto through the supply line 9 and then is exhausted therefrom through the exhaust line 10. Since a volume of the antechamber 3 confined by the boat waiting chamber 4 is set to be small, the oxygen concentration in the antechamber 3 can be kept low even though the amount of the nitrogen gas G flowing into the antechamber 3 is small. Accordingly, a formation of the natural oxide film can be prevented although the wafers W held in the boat 21 are exposed to the heat radiated from the process room 14a of the process tube 14 through the furnace mouth that is already opened by removing the shutter 18 for loading the boat 21 into the process room 14a.

Further, bad effect on the wafers W due to particulates formed from the boat elevator 19 can be reduced because the particulates are discharged from the antechamber 3 by making the clean nitrogen gas G continuously flow therethrough.

The feed screw and other parts of the boat elevator 19 are coated with grease having a heat resistant temperature of 260° C. under the atmospheric pressure. If a temperature of the antechamber 3 is equal to or greater than 260° C., the grease evaporates to generate organic substances, which can cause an organic pollution on the wafers W. In the present invention, however, the organic pollution due to the evaporation of the grease coated on the feed screw and other parts of the boat elevator 19 can be prevented because the elevator 19 is cooled by making the cold nitrogen gas G continuously flow through the antechamber 3, so that the generation of the organic substance can be prevented.

When the boat 21 reaches its uppermost position, the furnace mouth of the manifold 15 is closed to be airtightly sealed by a periphery of the sealing cap 20 supporting the boat 21. Therefore, the process room 14a becomes a hermetically closed state.

The hermetically closed process room 14a is evacuated to a predetermined level of vacuum, heated to a predetermined temperature by the heater unit 13 and supplied with a predetermined amount of a source gas through the gas supply line 16 to form a layer on the wafers W under a predetermined process condition.

After a predetermined period of time elapsed, the boat 21 is lowered by the boat elevator 19 to be unloaded from the process room 14a. At this moment, even though the processed wafers W are unloaded from the process room 14a to be disposed in the antechamber 3, the nitrogen gas G fills and flows through the antechamber 3 while keeping the oxygen concentration therein low, so that the formation of the natural oxide film on the processed wafers W with a high temperature can be prevented.

The processed wafers W loaded into the antechamber 3 are cooled by the cold nitrogen gas G flowing therethrough. After a temperature of the wafers W falls to a predetermined temperature, the first wafer loading/unloading opening 5 formed in the front wall of the boat waiting chamber 4 separating the wafer transfer room 22 from the antechamber 3 is opened by the gate 6. Then, the wafers W are picked up by the tweezers 35 of the wafer transfer system 30 entering the antechamber 3 through the first wafer loading/unloading opening 5 and unloaded from the boat 21. The wafers W supported by the tweezers 35 are transferred to the wafer transfer room 22 and then charged into and stored in the pod P disposed in the pod opener 41 with its opening opened. At this time, since the inner pressure in the wafer transfer room 22 is set to be less than that in the antechamber 3, the ambience of the wafer transfer room 22, i.e., the nitrogen gas G containing the atmosphere as an impurity is prevented from being introduced into the antechamber 3. In other words, the oxygen concentration in the antechamber 3 is maintained to be lower than that in the wafer transfer room 22 without being affected by the ambience in the wafer transfer chamber 23.

After a predetermined number of the processed wafers W are loaded into the pod P by performing such process as described above, the cap of the pod P is restored by the pod opener 41 so that the opening of the pod P is closed. Then, the pod P containing the processed wafers W is transferred to and disposed on a predetermined shelf plate 55 of the rotatable pod shelf 53 by the pod transfer system 56 to be stored temporarily thereon.

In the wafer unloading process from the boat 21 as described above, since the capacity of the boat 21 is several times greater than that of the pod P, the several pods P are transferred to the two loading ports 42 alternately and repeatedly. Further, the pod transferring process for the upper or lower loading port 42 is performed while the wafer transferring process for the pod P on the lower or upper loading port 42 is being performed. Therefore, the wafer transferring process can be performed without waiting for the pod transferring process to be done, so that the throughput of the batch-type CVD apparatus can be increased.

Next, the pod P containing the processed wafers W are transferred from the rotatable pod shelf 53 to the pod stage 52 through the pod loading/unloading opening 50 to be disposed thereon by the pod transfer system 56. The pod P disposed on the pod stage 52 is carried to a subsequent process by a transfer system.

Further, the pod transferring process between the rotatable pod shelf 53 and the pod stage 52 and the pod loading/unloading process for the pod stage 52 are performed while the film forming process on the wafers W in the process room 14a is being performed. Therefore, extension of the operation time of the batch-type CVD apparatus 1 can be prevented.

Next, the wafers W are batch-processed repeatedly as described above by the batch-type CVD apparatus 1.

Following effects can be achieved by the first preferred embodiment of the present invention.

1) The oxygen concentration in the antechamber 3 is set at a very low level (1 ppm or below in the preferred embodiment, preferably 0.1 ppm up to 1 ppm). Therefore, even though the wafers W in the antechamber 3 are exposed to the heat radiated from the process room 14a of the process tube 14, the formation of the natural oxide film can be prevented, so that the quality and the fidelity of the batch-type CVD apparatus and the method for fabricating the semiconductor devices can be improved. Further, a production yield of the method for fabricating the semiconductor device can be increased.

2) The antechamber 3 and the wafer transfer room 22 are separated from each other and filled with the nitrogen gas G flowing therethrough. Therefore, even though the atmosphere ambience is introduced into the wafer transfer room 22 while the wafers W are transferred from the pod P to the wafer transfer room 22, the nitrogen gas G filling and flowing through the wafer transfer room 22 prevents the oxygen concentration in the wafer transfer room 22 from being increased due to the introduced atmosphere, so that the oxygen concentration in the antechamber 3 is rarely affected by the atmosphere introduced into the wafer transfer room 22. In addition, since the oxygen concentration in the antechamber 3 (1 ppm or below) is set at a lower level than that in the wafer transfer chamber 23 (20 ppm or below), the oxygen concentration in the antechamber 3 can be constrained to have a value such that the natural oxide film formation on the wafers W exposed to the heat radiated from the process chamber 14a is prevented. Further, the quality and the fidelity of the film forming process can be improved without increasing an operation cost of the nitrogen gas G.

3) The volume of the antechamber 3 is small. Therefore, the oxygen concentration in the antechamber 3 can be constrained at a low level with a reduced amount of the nitrogen gas G, so that the operation cost of the batch-type CVD apparatus 1 and specially the film forming process can be drastically decreased.

4) The antechamber 3 and the wafer transfer room 22 are separated from each other and filled with the nitrogen gas G. Therefore, a process of replacing atmosphere ambience with the nitrogen gas ambience is unnecessary, so that a throughput of the film forming process of the batch-type CVD apparatus 1 and the method for fabricating semiconductor devices can be increased.

5) The inner pressure of the antechamber 3 is set at a value greater than that of the wafer transfer room 22. Therefore, the ambience in the wafer transfer room 22 is prevented from being introduced into the antechamber 3, so that the oxygen concentration in the antechamber 3 can be maintained at a value less than that in the wafer transfer room 22.

6) The clean nitrogen gas G is supplied to the antechamber 3 to fill it and flow therethrough. Therefore, the particulates generated from the boat elevator 19 and/or the wafer transfer system 30 are removed therefrom, so that a bad effect due to the particulates can be prevented.

7) The cold nitrogen gas G is supplied to the antechamber 3 to fill it and flow therethrough. Therefore, the boat elevator 19 is cooled effectively by the cold nitrogen gas G, so that the grease used for the boat elevator 19 can be kept from generating the organic substances.

8) The cold nitrogen gas G is supplied to the antechamber 3 to fill it and flow therethrough. Therefore, the processed wafers W are cooled rapidly after being unloaded from the process room 14a, so that the processed wafers W unloaded from the process room 14a can be transferred from the boat 21 without a long wait.

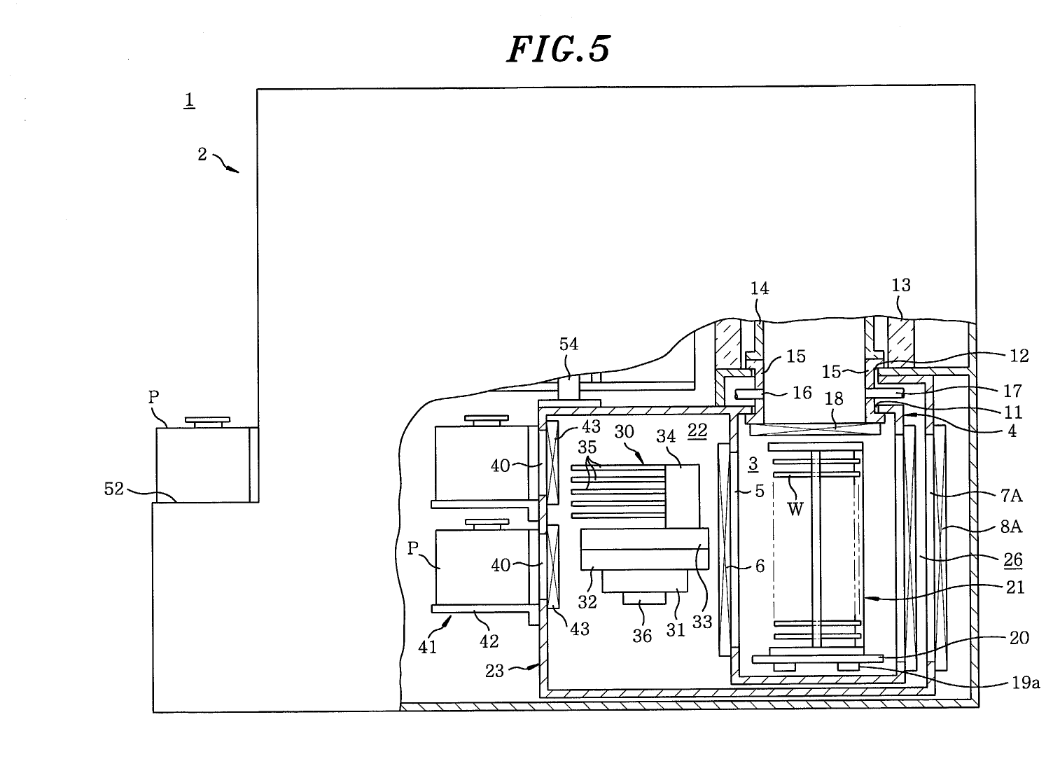

Referring to FIG. 5, there is shown a side view of a batch-type CVD apparatus 1 with a partial portion cross-sectioned in accordance with a second preferred embodiment.

The batch-type CVD apparatus in accordance with the second preferred embodiment is different from that in accordance with the first preferred embodiment in that the second preferred embodiment has a double shell structure with an outer shell, i.e., the wafer transfer chamber 23 and an inner shell, i.e., the boat waiting chamber 4. Further, in a rear wall of the wafer transfer chamber 23, a second maintenance opening 7A is formed, which is facing the gate 8 of the boat waiting chamber 4 and closed by a second closure 8A.

In the batch-type CVD apparatus 1 in accordance with the second preferred embodiment, the double shell structure forms an annular region 26 between the rear wall of the wafer transfer chamber 23 and the rear wall of the boat waiting chamber 4, so that the antechamber 3 can be more perfectly isolated from the ambience outside the housing 2.

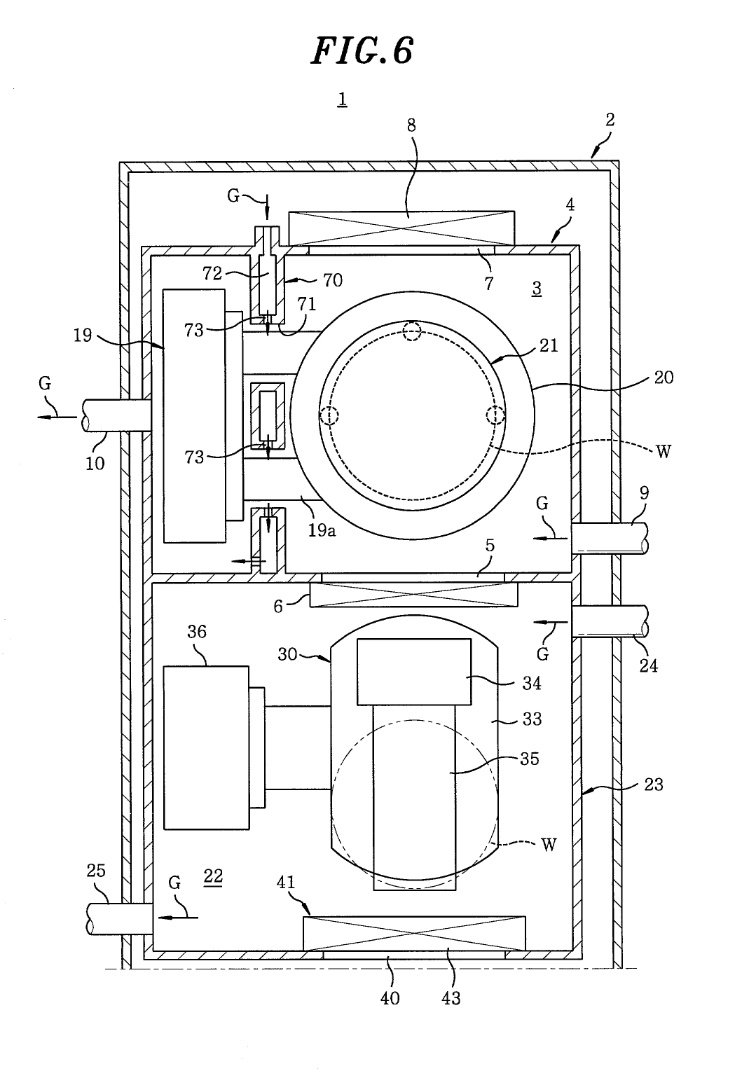

Referring to FIG. 6, there is shown a partial horizontal cross-sectional view of a batch-type CVD apparatus 1 in accordance with a third preferred embodiment of the present invention.

The batch-type CVD apparatus 1 in accordance with the third preferred embodiment is different from those in accordance with the previous preferred embodiments in that it has a cross wall 70 disposed between the boat elevator 19 and the boat 21 in the antechamber 3 to thereby divide the antechamber 3 into two portions, i.e., an elevator region in which the elevator 19 is installed and a boat region in which the boat 21 is installed. The cross wall 70 stands vertically and has two longitudinal openings 71 for allowing two arms of the lift arm 19a to pass therethrough, each longitudinal opening having a length somewhat greater than that of a moving stroke of the lift arm 19a. The cross wall 70 has a nitrogen gas passage 72 horizontally formed therein for allowing the nitrogen gas G to flow therethrough and communicates with a corresponding ejection opening 73, wherein each ejection opening 73 is formed in a side wall of the longitudinal opening 71. Further, the supply line 9 is connected to the boat waiting chamber 4 in such a manner that the nitrogen gas G is supplied directly to the boat region. The exhaust line 10 is connected to the boat waiting chamber 4 in such a manner that the elevator region can be evacuated first.

As a result, in the batch-type CVD apparatus 1 in accordance with the third preferred embodiment of the present invention, the wafers W held in the boat 21 can be more effectively prevented from being polluted by the particulates or the possible organic substances generated from the elevator 19 because the elevator region is separated and substantially isolated from the boat region by the cross wall 70. That is, since the supply line 9 supplies the nitrogen gas G to the boat region and the exhaust line 10 evacuates the elevator region, the nitrogen gas G in the antechamber 3 flows toward the boat elevator 19 from a side of the boat 21, thereby preventing the particulates or the possible organic substances generated from the boat elevator 19 from being introduced into the boat region. Further, the nitrogen gas G blown from the ejection openings 73 forms air curtains, which prevent the nitrogen gas G in the elevator region from being introduced into the boat region. It should be noted that a plurality of ejection openings 73 could be formed in a multilevel between the boat region and the elevator region so as to increase the effect of the air curtains.

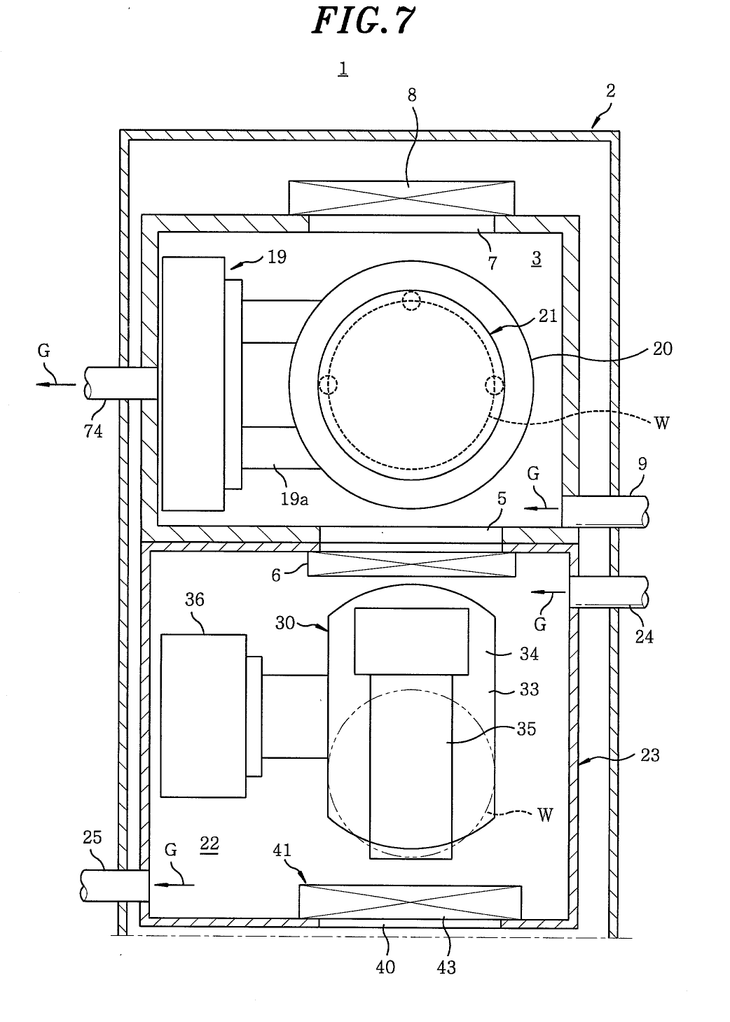

Referring to FIG. 7, there is shown a partial horizontal cross-sectional view of a batch-type CVD apparatus 1 in accordance with a fourth preferred embodiment of the present invention.

The batch-type CVD apparatus 1 in accordance with the fourth preferred embodiment is different from the previous preferred embodiments in that the boat waiting chamber 4 of the batch-type CVD apparatus 1 in accordance with the fourth preferred embodiment has a load-lock capability. That is, the boat waiting chamber 4 is made in an hermetic structure capable of withstanding against the atmospheric pressure, and provided with the supply line 9 for supplying the nitrogen gas G and the exhaust line 74 for evacuating the antechamber 3 to a certain specified level of vacuum and discharging the nitrogen gas G therefrom.

As a result, since the antechamber 3 is evacuated to a certain level of vacuum, the oxygen concentration of the antechamber can be drastically reduced. In addition, since the nitrogen gas G fills in and flows through the antechamber 3, moisture adhering to an inner surface of the walls of the boat waiting chamber 4 can be removed by the nitrogen gas G. Accordingly, the formation of the natural oxide film can be more effectively prevented.

Further, it should be noted that the preferred embodiments described above can be modified without departing from the scope of the present invention.

For instance, the present invention can be applied to the batch-type CVD apparatus having more than one boat even though the preferred embodiments of the present invention have one boat.

In addition, the present invention can be applied to the batch-type CVD apparatus having one, more than two pod openers disposed vertically or a plurality of the pod openers disposed horizontally.

Further, the substrate processing apparatus can be of the type capable of processing other substrate, e.g., photo masks, printed circuit boards, liquid crystal panels, compact disks and magnetic disk, than the semiconductor wafers.

The batch-type CVD apparatus can be of the type adapted to perform, e.g., an oxide film formation, a diffusion process or any other type of heat treating processes in place of the CVD.

Furthermore, it also should be appreciated that the present invention could be applicable to other types of substrate processing apparatuses, e.g., a batch-type horizontal apparatus for performing a diffusion and a CVD process, than the batch-type CVD apparatus described above.

While the invention has been shown and described with respect to the preferred embodiments, it will be understood by those skilled in the art that various changes and modifications may be made without departing from the spirit and scope of the invention as defined in the following claims.

What is claimed:

1. A substrate processing apparatus, which comprises:
a substrate holder for holding a plurality of wafers and being loaded therewith into a process tube through an opening in the process tube, in which a plurality of the wafers are processed;
a wafer transfer system for charging a plurality of the wafers to the wafer holder;
a boat waiting chamber installed on a line passing through the opening in the process tube and substantially hermetically accommodating the substrate holder before and after the substrate holder is loaded into and unloaded from the process tube; and
a wafer transfer chamber for substantially hermetically accommodating the wafer transfer system,
wherein an oxygen concentration in the boat waiting chamber is different from that in the wafer transfer chamber.

2. The substrate processing apparatus of claim 1, wherein the oxygen concentration in the boat waiting chamber is less than that in the wafer transfer chamber.

3. The substrate processing apparatus of claim 1, further comprising a housing for accommodating the boat waiting chamber and the wafer transfer chamber and insulating them from an ambience outside the housing,
wherein the boat waiting chamber is accommodated in the wafer transfer chamber to be insulated from an ambience inside the housing.

4. The substrate processing apparatus of claim 1, wherein the boat waiting chamber is installed adjacent to the wafer transfer chamber and configured to be evacuated to a vacuum.

5. The substrate processing apparatus of claim 2, wherein the oxygen concentration in the wafer transfer chamber is substantially equal to or less than 20 ppm and the oxygen concentration in the boat waiting chamber is substantially equal to or less than 1 ppm.

6. A method for fabricating a semiconductor device by using a substrate processing apparatus having:
a substrate holder for holding a plurality of wafers and being loaded therewith into a process tube through an opening in the process tube, in which a plurality of the wafers are processed;
a wafer transfer system for charging a plurality of the wafers to the wafer holder;
a boat waiting chamber installed on a line passing through the opening in the process tube and substantially hermetically accommodating the substrate holder before and after the substrate holder is loaded into and unloaded from the process tube; and
a wafer transfer chamber for substantially hermetically accommodating the wafer transfer system,
wherein an oxygen concentration in the boat waiting chamber is different from that in the wafer transfer chamber.
